(19) United States
(12) Patent Application Publication
(10) Pub. No.: US 2026/0282682 A1
(43) Pub. Date: Sep. 17, 2026

(54) DISPLAY DEVICE AND ELECTRONIC DEVICE INCLUDING THE DISPLAY DEVICE

(71) Applicant: Samsung Display Co., Ltd., Yongin-si (KR)

(72) Inventors: KYUNG-BAE KIM, Yongin-si (KR); KEONMIN OH, Yongin-si (KR); YONGHEE LEE, Yongin-si (KR); Yunjang Pyun, Yongin-si (KR)

(21) Appl. No.: 19/548,228

(22) Filed: Feb. 24, 2026

(30) Foreign Application Priority Data
Mar. 11, 2025 (KR) 10-2025-0031300

(51) Int. Cl. H10K 59/131

(52) U.S. Cl. CPC H10K 59/131

(57) ABSTRACT

A display device includes a substrate including a first well area. The first well area includes a first contact area, a second contact area spaced apart from the first contact area in a plan view, and a first channel area located between the first contact area and the second contact area, The display device includes a first gate pattern located on the substrate and including a first portion at least partially overlapping the first channel area of the substrate in the plan view, and a second portion protruding from the first portion. The display device includes a first contact pattern located on the first gate pattern and connected to the second portion of the first gate pattern through a first contact hole.

### CROSS REFERENCE RELATED TO THE APPLICATION

This application claims priority to Korean Patent Application No. 10-2025-0031300, filed on Mar. 11, 2025, and all the benefits accruing therefrom under 35 U.S.C. §119, the content of which in its entirety is herein incorporated by reference.

### BACKGROUND

### 1. Field

The present disclosure relates to a display device and an electronic device including the display device. More particularly, the present disclosure relates to a display device providing visual information and an electronic device including the display device.

### 2. Description of the Related Art

A display device is a device that displays an image for providing visual information to a user. Among display devices, an organic light emitting display device has recently attracted attention.

A head mounted display (“HMD”) including such a display device has been developed. The head mounted display is a glasses-type monitor device for virtual reality (“VR”) or augmented reality (“AR”), which is worn in form of glasses or a helmet and focuses images at a distance close to and in front of a user's eyes. An organic light emitting diode on Silicon (“OLEDoS”) display may be used in products such as the head mounted display.

### SUMMARY

Embodiments of the present disclosure provide a high-resolution display device.

Embodiments of the present disclosure provide an electronic device including the display device.

A display device according to an embodiment includes a substrate including a first well area including a first contact area, a second contact area spaced apart from the first contact area in a plan view, and a first channel area located between the first contact area and the second contact area, a first gate pattern located on the substrate and including a first portion at least partially overlapping the first channel area of the substrate in the plan view, and a second portion protruding from the first portion, and a first contact pattern located on the first gate pattern and connected to the second portion of the first gate pattern through a first contact hole.

In an embodiment, a width of the first portion of the first gate pattern in a first direction may be greater than a width of the second portion of the first gate pattern in the first direction.

In an embodiment, the second portion of the first gate pattern may be spaced apart from the first channel area of the substrate in the plan view.

In an embodiment, a portion of the first well area of the substrate and a portion of the first gate pattern may constitute a first transistor that provides a driving current to a light-emitting element.

In an embodiment, the substrate may further include a second well area including a third contact area, a fourth contact area spaced apart from the third contact area in the plan view, and a second channel area located between the third contact area and the fourth contact area.

In an embodiment, the display device may further include a second a gate pattern located on the substrate, spaced apart from the first gate pattern in the plan view, and at least partially overlapping the second channel area of the substrate in the plan view.

In an embodiment, the first well area of the substrate may extend in a first direction, and the second well area of the substrate may extend in a second direction intersecting the first direction.

In an embodiment, the second contact area of the substrate may be spaced apart from the first contact area of the substrate in the first direction, and the fourth contact area of the substrate may be spaced apart from the third contact area of the substrate in the second direction.

In an embodiment, a portion of the first well area of the substrate and a portion of the first gate pattern may constitute a first transistor that provides a driving current to a light-emitting element, and a portion of the second well area of the substrate and a portion of the second gate pattern may constitute a second transistor that provides a data voltage to a first node.

In an embodiment, the substrate may further include a third well area including a fifth contact area, a sixth contact area spaced apart from the fifth contact area in the plan view, and a third channel area located between the fifth contact area and the sixth contact area.

In an embodiment, the display device may further include a third gate pattern located on the substrate, spaced apart from the first gate pattern and the second gate pattern in the plan view, and at least partially overlapping the third channel area of the substrate in the plan view.

In an embodiment, the first well area of the substrate may extend in a first direction, and each of the second well area and the third well area of the substrate may extend in a second direction intersecting the first direction.

In an embodiment, the first contact pattern may be connected to the third contact area of the substrate through a third contact hole.

In an embodiment, the substrate may further include a fourth well area spaced apart from the first well area in the plan view.

In an embodiment, the display device may further include a second contact pattern located on the first gate pattern and connected to the fourth well area through a fifth contact hole and a fourth contact line located on the second contact pattern, to which a first power voltage is applied, and connected to the second contact pattern through an eleventh contact hole.

In an embodiment, each of the first well area and the fourth well area of the substrate may extend in a first direction.

In an embodiment, the first gate pattern may be located in a display area in which pixel is arranged, a width of the pixel in a first direction may be greater than a width of the pixel in a second direction intersecting the first direction, and the first well area may extend in the first direction.

A display device according to an embodiment includes a substrate including a first well area including a first contact area, a second contact area spaced apart from the first contact area in a plan view, and a first channel area located between the first contact area and the second contact area and extending in a first direction and a second well area including a third contact area, a fourth contact area spaced apart from the third contact area in the plan view, and a second channel area located between the third contact area and the fourth contact area and extending in a second direction intersecting the first direction, a first gate pattern located on the substrate and at least partially overlapping the first channel area of the substrate in the plan view, and a second gate pattern located on the substrate, spaced apart from the first gate pattern in the plan view, and at least partially overlapping the second channel area of the substrate in the plan view.

In an embodiment, a portion of the first well area of the substrate and a portion of the first gate pattern may constitute a first transistor that provides a driving current to a light-emitting element, and a portion of the second well area of the substrate and a portion of the second gate pattern may constitute a second transistor that provides a data voltage to a first node.

In an embodiment, the substrate further may include a third well area extending in the second direction and including a fifth contact area, a sixth contact area spaced apart from the fifth contact area in the plan view, and a third channel area located between the fifth contact area and the sixth contact area.

In an embodiment, the display device may further include a third gate pattern located on the substrate, spaced apart from the first gate pattern and the second gate pattern in the plan view, and at least partially overlapping the third channel area of the substrate in the plan view.

An electronic device according to an embodiment includes a substrate including a first well area including a first contact area, a second contact area spaced apart from the first contact area in a plan view, and a first channel area located between the first contact area and the second contact area, a first gate pattern located on the substrate and including a first portion at least partially overlapping the first channel area of the substrate in the plan view, and a second portion protruding from the first portion, a first contact pattern located on the first gate pattern and connected to the second portion of the first gate pattern through a first contact hole and a memory configured to store data information.

In an embodiment, a width of the first portion of the first gate pattern in a first direction may be greater than a width of the second portion of the first gate pattern in the first direction.

In an embodiment, the second portion of the first gate pattern may be spaced apart from the first channel area of the substrate in the plan view.

A display device according to an embodiment may include a substrate including a first well area including a first contact area, a second contact area spaced apart from the first contact area in a plan view, and a first channel area located between the first contact area and the second contact area, a first gate pattern located on the substrate and including a first portion at least partially overlapping the first channel area of the substrate in the plan view, and a second portion protruding from the first portion, and a first contact pattern located on the first gate pattern and connected to the second portion of the first gate pattern through a first contact hole.

Accordingly, sufficient space for arranging a second transistor and a third transistor may be secured, such that a distance between the first transistor and the second transistor in a plan view may be reduced. In some aspects, a distance between the first transistor and the third transistor in the plan view may be reduced. Accordingly, a pixel driving circuit portion suitable for a high-resolution display device may be provided.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a block diagram illustrating the display device of FIG. 1.

FIG. 3 is a circuit diagram illustrating a pixel included in the display device of FIG. 1.

FIGS. 4, 5, 6, 7, 8, 9, and 10 are plan views illustrating a partial area of the display device of FIG. 1.

FIG. 11 is a cross-sectional view taken along the line I-I` of the display device of FIG. 10.

FIG. 12 is a block diagram illustrating an electronic device according to embodiments.

FIG. 13 is a schematic diagram of an electronic device according to various embodiments.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as "A or B”, "at least one of A and B”, "at least one of A or B”, "A, B, or C”, "at least one of A, B, and C”, and "at least one of A, B, or C”, may include any one of, or all possible combinations of the items enumerated together in a corresponding one of the phrases.

It is to be understood that if an element (e.g., a first element) is referred to, with or without the term "operatively" or "communicatively", as "coupled with”, "coupled to”, "connected with”, or "connected to" another element (e.g., a second element), it means that the element may be coupled with the other element directly (e.g., wiredly), wirelessly, or via a third element.

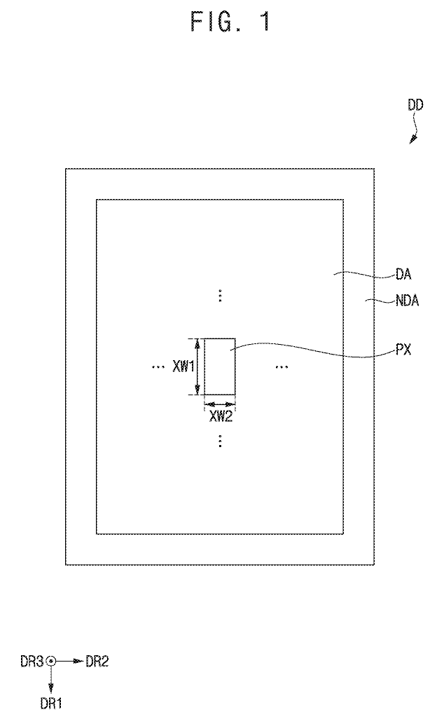

FIG. 1 is a plan view illustrating a display device according to an embodiment.

Referring to FIG. 1, the display device DD according to an embodiment may include a display area DA and a non-display area NDA.

The display area DA may be defined as an area capable of generating light or displaying an image by adjusting transmittance of light provided from an external light source. The non-display area NDA may be an area that does not display an image. In some aspects, the non-display area NDA may surround at least a portion of the display area DA. For example, the non-display area NDA may entirely surround the display area DA.

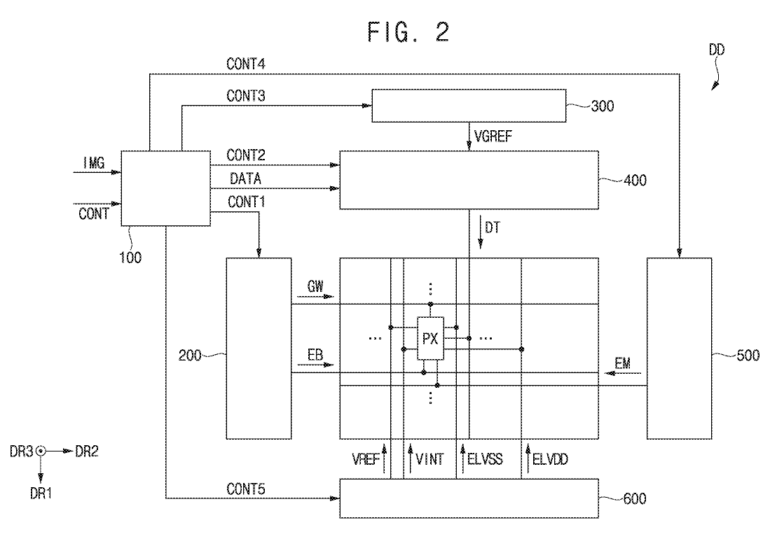

A plurality of pixels PX may be arranged in the display area DA. The plurality of pixels PX may be repeatedly arranged along a first direction DR1 and a second direction DR2 intersecting the first direction DR1. Each of the plurality of pixels PX may emit light. A plurality of drivers may be arranged in the non-display area NDA. The plurality of drivers will be described herein with reference to FIG. 2.

In an embodiment, the first direction DR1 and the second direction DR2 intersecting the first direction DR1 may be defined. For example, the second direction DR2 may be substantially perpendicular to the first direction DR1. However, embodiments of the present disclosure are not necessarily limited thereto, and the second direction DR2 may form an acute angle or an obtuse angle with the first direction DR1. In some aspects, a third direction DR3 intersecting a plane formed by the first direction DR1 and the second direction DR2 may be defined. For example, the third direction DR3 may be substantially perpendicular to the plane formed by the first direction DR1 and the second directions DR2. However, embodiments of the present disclosure are not necessarily limited thereto, and the third direction DR3 may form an acute angle or an obtuse angle with the plane formed by the first direction DR1 and the second direction DR2.

FIG. 2 is a block diagram illustrating the display device of FIG. 1.

Referring to FIG. 2, the display device DD may include a driving controller 100, a scan driver 200, a gamma reference voltage generator 300, a data driver 400, a light-emitting control driver 500, and a voltage generator 600. As described herein, the plurality of drivers may be arranged in the non-display area (e.g., the non-display area NDA of FIG. 1), and the plurality of drivers may include the driving controller 100, the scan driver 200, the gamma reference voltage generator 300, the data driver 400, the light-emitting control driver 500, and the voltage generator 600.

The driving controller 100 may receive input image data IMG and an input control signal CONT from an external device. In an embodiment, the input image data IMG may include red image data, green image data, and blue image data. In another embodiment, the input image data IMG may include white image data. In another embodiment, the input image data IMG may include magenta image data, yellow image data, and cyan image data. The input control signal CONT may include a master clock signal, a data enable signal, and/or the like. The input control signal CONT may further include a vertical synchronization signal and a horizontal synchronization signal.

The driving controller 100 may receive an input control signal CONT, generate a first control signal CONT1, and output the first control signal CONT1 to the scan driver 200. The first control signal CONT1 may include a vertical start signal and a gate clock signal. The driving controller 100 may receive the input control signal CONT, generate a second control signal CONT2, and output the second control signal CONT2 to the data driver 400. The second control signal CONT2 may include a horizontal start signal and a load signal. The driving controller 100 may receive the input control signal CONT, generate a third control signal CONT3, and output the third control signal CONT3 to the gamma reference voltage generator 300. The driving controller 100 may receive the input control signal CONT, generate a fourth control signal CONT4, and output the fourth control signal CONT4 to the light-emitting control driver 500. The driving controller 100 may receive the input control signal CONT, generate a fifth control signal CONT5, and output the fifth control signal CONT5 to the voltage generator 600. The driving controller 100 may receive input image data IMG, generate a data signal DATA, and output the data signal DATA to the data driver 400.

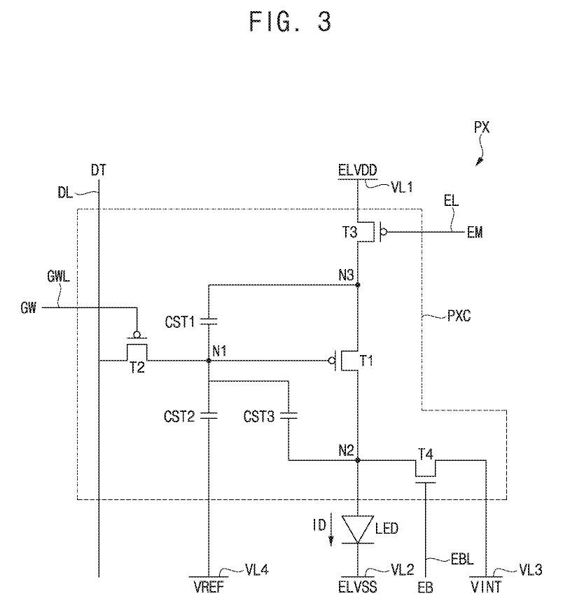

The scan driver 200 may receive the first control signal CONT1 and output a scan signal to scan lines. For example, the scan driver 200 may output a first scan signal GW to a first scan line (e.g., a first scan line GWL of FIG. 3) and may output a second scan signal EB to a second scan line (e.g., a second scan line EBL of FIG. 3). The scan driver 200 may provide the first scan signal GW and the second scan signal EB to the plurality of pixels PX.

The gamma reference voltage generator 300 may receive the third control signal CONT3 from the driving controller 100 and generate a gamma reference voltage VGREF. The gamma reference voltage generator 300 may provide the gamma reference voltage VGREF to the data driver 400. The gamma reference voltage VGREF may have a value corresponding to the data signal DATA.

The data driver 400 may receive the second control signal CONT2 and the data signal DATA from the driving controller 100. In some aspects, the data driver 400 may receive the gamma reference voltage VGREF from the gamma reference voltage generator 300. The data driver 400 may convert the data signal DATA into an analog data voltage DT using the gamma reference voltage VGREF. The data driver 400 may provide the data voltage DT to the plurality of pixels PX.

The light-emitting control driver 500 may receive the fourth control signal CONT4 from the driving controller 100 and generate a light-emitting control signal EM. The light-emitting control driver 500 may provide the light-emitting control signal EM to the plurality of pixels PX.

The voltage generator 600 may receive the fifth control signal CONT5 from the driving controller 100 and generate a reference voltage VREF, an initialization voltage VINT, a first power voltage ELVDD, and a second power voltage ELVSS. The voltage generator 600 may provide the reference voltage VREF, the initialization voltage VINT, the first power voltage ELVDD, and the second power voltage ELVSS to the plurality of pixels PX.

FIG. 2 may illustrate one example of positions of the plurality of drivers. For example, as illustrated in FIG. 2, the scan driver 200 may be spaced apart from the display area DA in a direction opposite to the second direction DR2, the data driver 400 may be spaced apart from the display area DA in a direction opposite to the first direction DR1, the light-emitting control driver 500 may be spaced apart from the display area DA in the second direction DR2, and the voltage generator 600 may be spaced apart from the display area DA in the first direction DR1. However, embodiments of the present disclosure are not necessarily limited thereto, and the positions of the plurality of drivers may vary depending on embodiments.

FIG. 3 is a circuit diagram illustrating a pixel included in the display device of FIG. 1.

Referring to FIG. 3, each of the plurality of pixels PX may include a light-emitting element LED and a pixel driving circuit portion PXC electrically connected to the light-emitting element LED.

In an embodiment, the pixel driving circuit portion PXC may include a first transistor T1, a second transistor T2, a third transistor T3, a fourth transistor T4, a first capacitor CST1, a second capacitor CST2, and a third capacitor CST3.

In an embodiment, each of the first transistor T1, the second transistor T2, and the third transistor T3 may be a PMOS transistor, and the fourth transistor T4 may be an NMOS transistor. However, embodiments of the present disclosure are not necessarily limited thereto, and types of the first transistor T1, the second transistor T2, the third transistor T3, and the fourth transistor T4 may vary depending on embodiments. For example, each of the first transistor T1, the second transistor T2, the third transistor T3, and the fourth transistor T4 may be a PMOS transistor.

The pixel driving circuit portion PXC may be electrically connected to a first voltage line VL1, a second voltage line VL2, a third voltage line VL3, a fourth voltage line VL4, a first scan line GWL, a second scan line EBL, a data line DL, and a light-emitting control line EL.

The first voltage line VL1 may provide a first power voltage ELVDD to the pixel driving circuit portion PXC. The second voltage line VL2 may provide a second power voltage ELVSS to the pixel driving circuit portion PXC. In an embodiment, a voltage level of the first power voltage ELVDD may be higher than a voltage level of the second power voltage ELVSS. The third voltage line VL3 may provide an initialization voltage VINT to the pixel driving circuit portion PXC. The fourth voltage line VL4 may provide a reference voltage VREF to the pixel driving circuit portion PXC. The first scan line GWL may provide a first scan signal GW to the pixel driving circuit portion PXC. The second scan line EBL may provide a second scan signal EB to the pixel driving circuit portion PXC. The light-emitting control line EL may provide a light-emitting control signal EM to the pixel driving circuit portion PXC.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide a driving current ID to the light-emitting element LED.

The second transistor T2 may include a gate electrode, a first electrode, and a second electrode. The gate electrode of the second transistor T2 may be connected to the first scan line GWL. The first electrode of the second transistor T2 may be connected to the data line DL. The second electrode of the second transistor T2 may be connected to the first node N1.

The gate electrode of the second transistor T2 may receive the first scan signal GW through the first scan line GWL. The second transistor T2 may be turned on or off in response to the first scan signal GW. In an example in which the second transistor T2 is a PMOS transistor, the second transistor T2 may be turned off when the first scan signal GW has a positive voltage level and may be turned on when the first scan signal GW has a negative voltage level. In some aspects, when the second transistor T2 is an NMOS transistor, the second transistor T2 may be turned off when the first scan signal GW has a negative voltage level and may be turned on when the first scan signal GW has a positive voltage level. The first electrode of the second transistor T2 may receive the data voltage DT through the data line DL. The second electrode of the second transistor T2 may provide the data voltage DT to the first node N1 during a period in which the second transistor T2 is turned on. Accordingly, the second transistor T2 may drive the first transistor T1.

The third transistor T3 may include a gate electrode, a first electrode, and a second electrode. The gate electrode of the third transistor T3 may be connected to the light-emitting control line EL. The first electrode of the third transistor T3 may be connected to the first voltage line VL1. The second electrode of the third transistor T3 may be connected to the third node N3.

The gate electrode of the third transistor T3 may receive the light-emitting control signal EM through the light-emitting control line EL. The third transistor T3 may be turned on or off in response to the light-emitting control signal EM. In an example in which the third transistor T3 is a PMOS transistor, the third transistor T3 may be turned off when the light-emitting control signal EM has a positive voltage level and may be turned on when the light-emitting control signal EM has a negative voltage level. In some aspects, when the third transistor T3 is an NMOS transistor, the third transistor T3 may be turned off when the light-emitting control signal EM has a negative voltage level and may be turned on when the light-emitting control signal EM has a positive voltage level. The first electrode of the third transistor T3 may receive the first power voltage ELVDD through the first voltage line VL1. The third transistor T3 may provide the first power voltage ELVDD to the third node N3 during a period in which the third transistor T3 is turned on.

The fourth transistor T4 may include a gate electrode, a first electrode, and a second electrode. The gate electrode of the fourth transistor T4 may be connected to the second scan line EBL. The first electrode of the fourth transistor T4 may be connected to the third voltage line VL3. The second electrode of the fourth transistor T4 may be connected to the second node N2.

The gate electrode of the fourth transistor T4 may receive the second scan signal EB through the second scan line EBL. The fourth transistor T4 may be turned on or off in response to the second scan signal EB. In an example in which the fourth transistor T4 is an NMOS transistor, the fourth transistor T4 may be turned off when the second scan signal EB has a negative voltage level and may be turned on when the second scan signal EB has a positive voltage level. In some aspects, when the fourth transistor T4 is a PMOS transistor, the fourth transistor T4 may be turned off when the second scan signal EB has a positive voltage level and may be turned on when the second scan signal EB has a negative voltage level. The first electrode of the fourth transistor T4 may receive the initialization voltage VINT through the third voltage line VL3. The fourth transistor T4 may provide the initialization voltage VINT to the second node N2 during a period in which the fourth transistor T4 is turned on.

The first capacitor CST1 may include a first electrode and a second electrode. The first electrode of the first capacitor CST1 may be connected to the third node N3. The second electrode of the first capacitor CST1 may be connected to the first node N1.

The second capacitor CST2 may include a first electrode and a second electrode. The first electrode of the second capacitor CST2 may be connected to the fourth voltage line VL4. The first electrode of the second capacitor CST2 may receive the reference voltage VREF through the fourth voltage line VL4. The second electrode of the second capacitor CST2 may be connected to the first node N1.

The third capacitor CST3 may include a first electrode and a second electrode. The first electrode of the third capacitor CST3 may be connected to the second node N2. The second electrode of the third capacitor CST3 may be connected to the first node N1.

The light-emitting element LED may include a first electrode and a second electrode. The first electrode of the light-emitting element LED may be connected to the second node N2. The second electrode of the light-emitting element LED may be connected to the second voltage line VL2. The second electrode of the light-emitting element LED may receive the second power voltage ELVSS through the second voltage line VL2. For example, the first electrode of the light-emitting element LED may be an anode electrode, and the second electrode of the light-emitting element LED may be a cathode electrode, but embodiments of the present disclosure are not necessarily limited thereto.

As illustrated in FIG. 3, the pixel driving circuit portion PXC may include four transistors and three capacitors. However, embodiments of the present disclosure are not necessarily limited thereto, and the number of transistors and the number of capacitors included in the pixel driving circuit portion PXC may vary depending on embodiments.

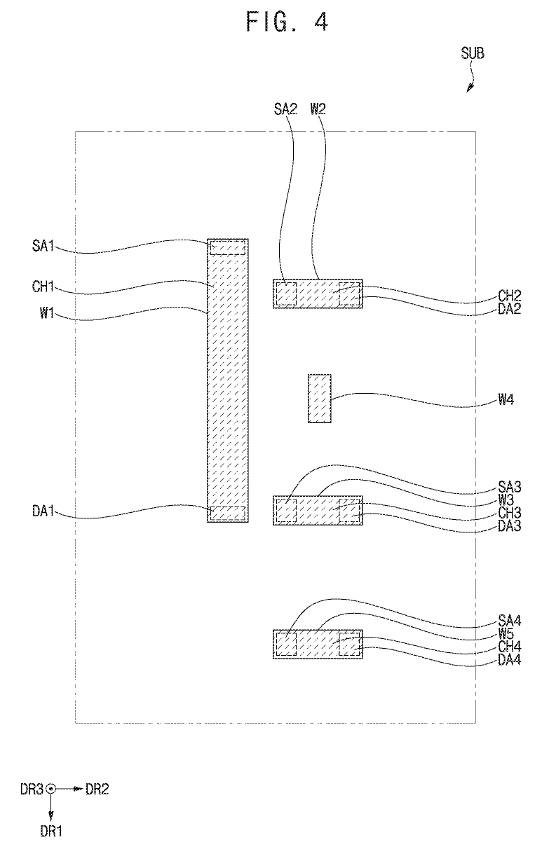

FIGS. 4, 5, 6, 7, 8, 9, and 10 are plan views illustrating a partial area of the display device of FIG. 1.

Referring to FIG. 4, the display device (e.g., the display device DD of FIG. 1) may include a substrate SUB. The substrate SUB may be a base of the display device. In an embodiment, the substrate SUB may be a silicon substrate. For example, the substrate SUB may be a P-type silicon substrate or an N-type silicon substrate. In this case, the P may refer to a hole, and the N may refer to an electron.

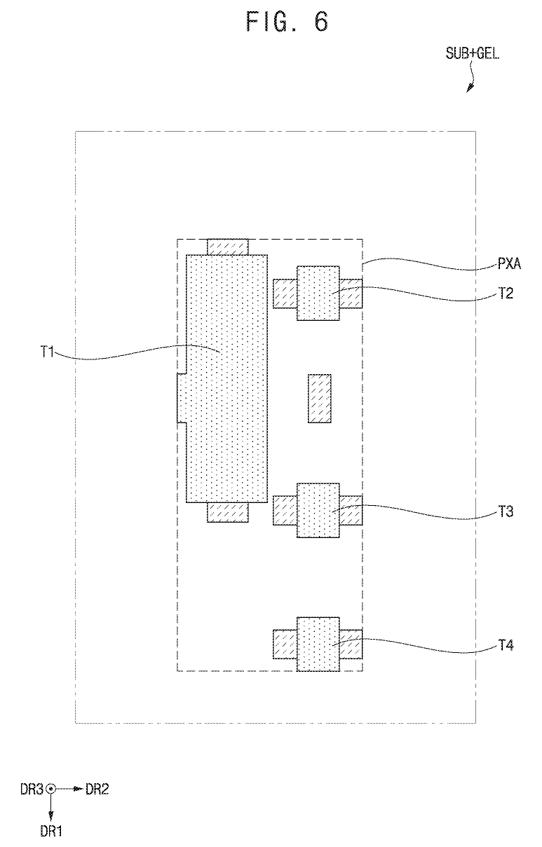

The substrate SUB may include a first well area W1, a second well area W2, a third well area W3, a fourth well area W4, and a fifth well area W5. The first well area W1 may be a P-well or an N-well depending on a type of the first transistor (e.g., the first transistor T1 of FIG. 6) and a type of the substrate SUB. The second well area W2 may be a P-well or an N-well depending on a type of the second transistor (e.g., the second transistor T2 of FIG. 6) and the type of the substrate SUB. The third well area W3 may be a P-well or an N-well depending on a type of the third transistor (e.g., the third transistor T3 of FIG. 6) and the type of the substrate SUB. The fifth well area W5 may be a P-well or an N-well depending on a type of the fourth transistor (e.g., the fourth transistor T4 of FIG. 6) and the type of the substrate SUB. In an embodiment, the fourth well area W4 may be a P-well. However, embodiments of the present disclosure are not necessarily limited thereto, and the fourth well area W4 may also be an N-well.

The first well area W1 may include a first contact area SA1, a second contact area DA1, and a first channel area CH1 located between the first contact area SA1 and the second contact area DA1. The first contact area SA1 and the second contact area DA1 may be spaced apart in a plan view. For example, the second contact area DA1 may be spaced apart from the first contact area SA1 in the first direction DR1. In an embodiment, the first well area W1 may extend in the first direction DR1. For example, the first well area W1 may have a rectangular shape extending in the first direction DR1 in the plan view, but embodiments of the present disclosure are not necessarily limited thereto.

In an embodiment, the first contact area SA1 and the second contact area DA1 may be a P-source area and a P-drain area, respectively, but embodiments of the present disclosure are not necessarily limited thereto, and the first contact area SA1 and the second contact area DA1 may also be an N-source area and an N-drain area, respectively.

The second well area W2 may include a third contact area SA2, a fourth contact area DA2, and a second channel area CH2 located between the third contact area SA2 and the fourth contact area DA2. The third contact area SA2 and the fourth contact area DA2 may be spaced apart from each other in the plan view. For example, the fourth contact area DA2 may be spaced apart from the third contact area SA2 in the second direction DR2. In an embodiment, the second well area W2 may extend in the second direction DR2. For example, the second well area W2 may have a rectangular shape extending in the second direction DR2 in the plan view, but embodiments of the present disclosure are not necessarily limited thereto.

In an embodiment, the third contact area SA2 and the fourth contact area DA2 may be a P-source area and a P-drain area, respectively, but embodiments of the present disclosure are not necessarily limited thereto, and the third contact area SA2 and the fourth contact area DA2 may also be an N-source area and an N-drain area, respectively.

The third well area W3 may include a fifth contact area SA3, a sixth contact area DA3, and a third channel area CH3 located between the fifth contact area SA3 and the sixth contact area DA3. The fifth contact area SA3 and the sixth contact area DA3 may be spaced apart from each other in the plan view. For example, the sixth contact area DA3 may be spaced apart from the fifth contact area SA3 in the second direction DR2. In an embodiment, the third well area W3 may extend in the second direction DR2. For example, the third well area W3 may have a rectangular shape extending in the second direction DR2 in the plan view, but embodiments of the present disclosure are not necessarily limited thereto.

In an embodiment, the fifth contact area SA3 and the sixth contact area DA3 may be a P-source area and a P-drain area, respectively, but embodiments of the present disclosure are not necessarily limited thereto, and the fifth contact area SA3 and the sixth contact area DA3 may also be an N-source area and an N-drain area, respectively.

The fifth well area W5 may include a seventh contact area SA4, an eighth contact area DA4, and a fourth channel area CH4 located between the seventh contact area SA4 and the eighth contact area DA4. The seventh contact area SA4 and the eighth contact area DA4 may be spaced apart from each other in the plan view. For example, the eighth contact area DA4 may be spaced apart from the seventh contact area SA4 in the second direction DR2. In an embodiment, the fifth well area W5 may extend in the second direction DR2. For example, the fifth well area W5 may have a rectangular shape extending in the second direction DR2 in the plan view, but embodiments of the present disclosure are not necessarily limited thereto.

In an embodiment, the seventh contact area SA4 and the eighth contact area DA4 may be an N-source area and an N-drain area, respectively, but embodiments of the present disclosure are not necessarily limited thereto, and the seventh contact area SA4 and the eighth contact area DA4 may also be a P-source area and a P-drain area, respectively.

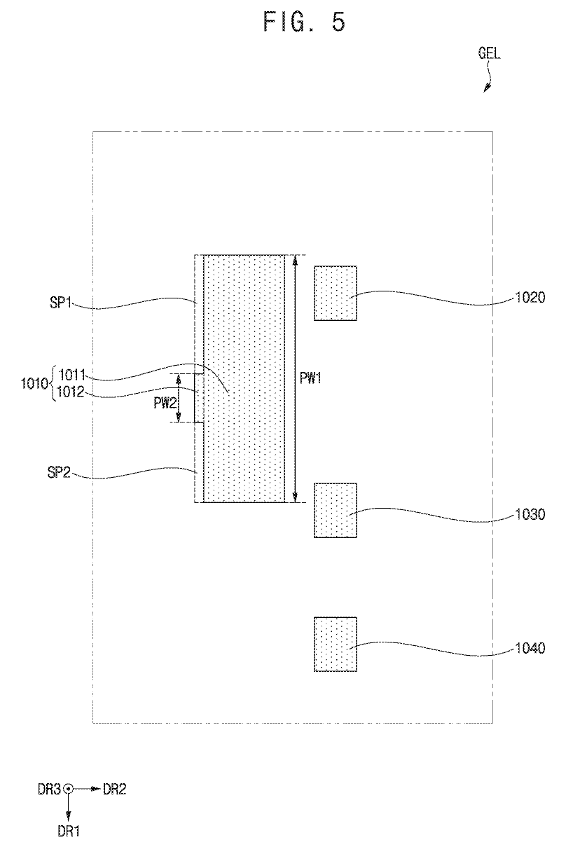

Referring to FIG. 5, the display device may further include a gate layer GEL. The gate layer GEL may be located on the substrate (e.g., the substrate SUB of FIG. 4). The gate layer GEL may include a first gate pattern 1010, a second gate pattern 1020, a third gate pattern 1030, and a fourth gate pattern 1040. The first gate pattern 1010, the second gate pattern 1020, the third gate pattern 1030, and the fourth gate pattern 1040 may be spaced apart from each other in the plan view.

In an embodiment, the first gate pattern 1010 may include a first portion 1011 and a second portion 1012. The second portion 1012 may be a portion protruding from the first portion 1011. For example, the second portion 1012 may be a portion protruding from the first portion 1011 in a direction opposite to the second direction DR2. In an embodiment, a width PW1 of the first portion 1011 in the first direction DR1 may be greater than a width PW2 of the second portion 1012 in the first direction DR1. In some aspects, a width of the first portion 1011 in the second direction DR2 may be greater than a width of the second portion 1012 in the second direction DR2.

The gate layer GEL may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other.

Referring to FIGS. 4, 5, and 6, the first transistor T1 may include a portion of the first well area W1 and a portion of the first gate pattern 1010. For example, the first transistor T1 may include the first contact area SA1, the second contact area DA1, the first channel area CH1, and a portion of the first gate pattern 1010 overlapping the first channel area CH1 in the plan view.

In an embodiment, the first transistor T1 may include the first contact area SA1, the second contact area DA1, the first channel area CH1, and a portion of the first portion 1011 overlapping the first channel area CH1 in the plan view. For example, the first portion 1011 may at least partially overlap the first channel area CH1 in the plan view. The second portion 1012 may be spaced apart from the first channel area CH1 in the plan view. The portion of the first portion 1011 overlapping the first channel area CH1 in the plan view may be referred to as a gate electrode of the first transistor T1.

The second transistor T2 may include a portion of the second well area W2 and a portion of the second gate pattern 1020. For example, the second transistor T2 may include the third contact area SA2, the fourth contact area DA2, the second channel area CH2, and a portion of the second gate pattern 1020 overlapping the second channel area CH2 in the plan view. The portion of the second gate pattern 1020 overlapping the second channel area CH2 in the plan view may be referred to as a gate electrode of the second transistor T2.

The third transistor T3 may include a portion of the third well area W3 and a portion of the third gate pattern 1030. For example, the third transistor T3 may include the fifth contact area SA3, the sixth contact area DA3, the third channel area CH3, and a portion of the third gate pattern 1030 overlapping the third channel area CH3 in the plan view. The portion of the third gate pattern 1030 overlapping the third channel area CH3 in the plan view may be referred to as a gate electrode of the third transistor T3.

The fourth transistor T4 may include a portion of the fifth well area W5 and a portion of the fourth gate pattern 1040. For example, the fourth transistor T4 may include the seventh contact area SA4, the eighth contact area DA4, the fourth channel area CH4, and a portion of the fourth gate pattern 1040 overlapping the fourth channel area CH4 in the plan view. The portion of the fourth gate pattern 1040 overlapping the fourth channel area CH4 in the plan view may be referred to as a gate electrode of the fourth transistor T4.

The first transistor T1 of FIG. 6 may substantially correspond to the first transistor T1 of FIG. 3, the second transistor T2 of FIG. 6 may substantially correspond to the second transistor T2 of FIG. 3, the third transistor T3 of FIG. 6 may substantially correspond to the third transistor T3 of FIG. 3, and the fourth transistor T4 of FIG. 6 may substantially correspond to the fourth transistor T4 of FIG. 3, but embodiments of the present disclosure are not necessarily limited thereto.

Referring to FIGS. 1 and 6, in an embodiment, each of the plurality of pixels PX may have a first width XW1 in the first direction DR1 and a second width XW2 in the second direction DR2. For example, an area in which one of the plurality of pixels PX is arranged may correspond to a pixel area PXA of FIG. 6, and the pixel area PXA may have the first width XW1 in the first direction DR1 and the second width XW2 in the second direction DR2. In an embodiment, the first transistor T1, the second transistor T2, the third transistor T3, and the fourth transistor T4 may be arranged in the pixel area PXA. For example, the pixel area PXA may refer to an area in which the first transistor T1, the second transistor T2, the third transistor T3, and the fourth transistor T4 are arranged. In an embodiment, the light-emitting element (e.g., the light-emitting element LED of FIG. 3) may be arranged in the pixel area PXA. In an embodiment, the first width XW1 of each of the plurality of pixels PX in the first direction DR1 may be greater than the second width XW2 in the second direction DR2.

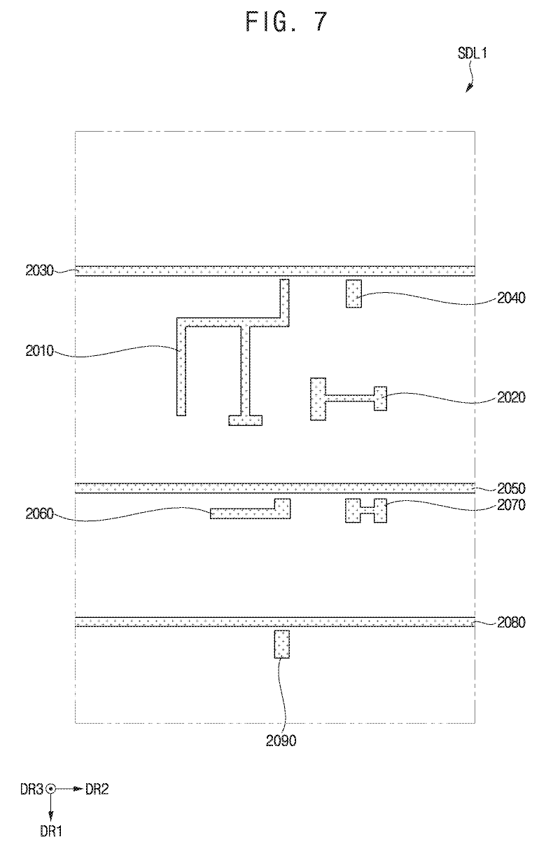

Referring to FIG. 7, the display device may further include a first contact layer SDL1. The first contact layer SDL1 may be located on the gate layer (e.g., the gate layer GEL of FIG. 6). The first contact layer SDL1 may include a first contact pattern 2010, a second contact pattern 2020, a third contact pattern 2030, a fourth contact pattern 2040, a fifth contact pattern 2050, a sixth contact pattern 2060, a seventh contact pattern 2070, an eighth contact pattern 2080, and a ninth contact pattern 2090. The first contact pattern 2010, the second contact pattern 2020, the third contact pattern 2030, the fourth contact pattern 2040, the fifth contact pattern 2050, the sixth contact pattern 2060, the seventh contact pattern 2070, the eighth contact pattern 2080, and the ninth contact pattern 2090 may be spaced apart from each other in the plan view.

The first scan signal (e.g., the first scan signal GW of FIG. 3) may be applied to the third contact pattern 2030. For example, the third contact pattern 2030 may substantially correspond to the first scan line (e.g., the first scan line GWL of FIG. 3), but embodiments of the present disclosure are not necessarily limited thereto. The third contact pattern 2030 may extend in the second direction DR2.

The light-emitting control signal (e.g., the light-emitting control signal EM of FIG. 3) may be applied to the fifth contact pattern 2050. For example, the fifth contact pattern 2050 may substantially correspond to the light-emitting control line (e.g., the light-emitting control line EL of FIG. 3), but embodiments of the present disclosure are not necessarily limited thereto. The fifth contact pattern 2050 may extend in the second direction DR2.

The second scan signal (e.g., the second scan signal EB of FIG. 3) may be applied to the eighth contact pattern 2080. For example, the eighth contact pattern 2080 may substantially correspond to the second scan line (e.g., the second scan line EBL of FIG. 3), but embodiments of the present disclosure are not necessarily limited thereto.

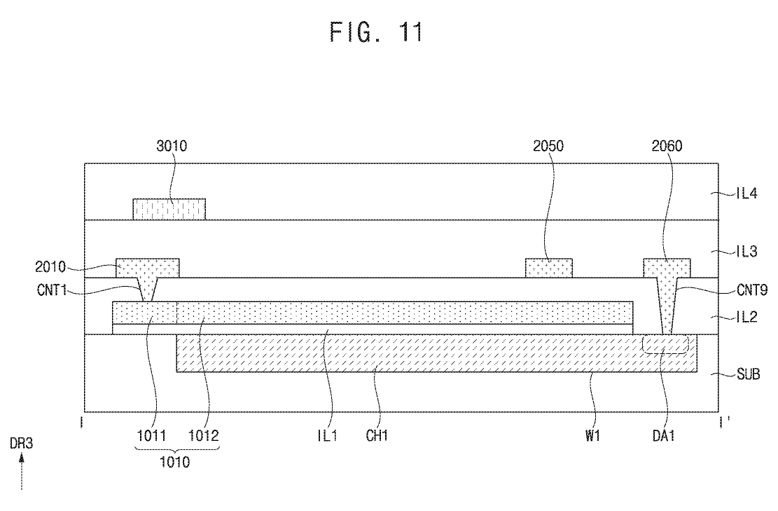

Referring to FIGS. 4, 5, and 8, the first contact pattern 2010 may be connected to the first gate pattern 1010. In an embodiment, the first contact pattern 2010 may be connected to the second portion 1012. For example, the first contact pattern 2010 may be connected to the second portion 1012 through a first contact hole CNT1 and a second contact hole CNT2. Each of the first contact hole CNT1 and the second contact hole CNT2 may penetrate a portion of a second insulating layer (e.g., a second insulating layer IL2 of FIG. 11). The first contact pattern 2010 may be connected to the gate electrode of the first transistor T1. For example, the first contact pattern 2010 may be connected to the gate electrode of the first transistor T1 through the second portion 1012, the first contact hole CNT1, and the second contact hole CNT2.

The first contact pattern 2010 may be connected to the second transistor T2. For example, the first contact pattern 2010 may be connected to the third contact area SA2. For example, the first contact pattern 2010 may be connected to the third contact area SA2 through a third contact hole CNT3 and a fourth contact hole CNT4. Each of the third contact hole CNT3 and the fourth contact hole CNT4 may penetrate the second insulating layer. The gate electrode of the first transistor T1 and the second transistor T2 may be connected to each other through the first contact pattern 2010. For example, the gate electrode of the first transistor T1 and the third contact area SA2 of the second transistor T2 may be connected to each other through the first contact pattern 2010.

The second contact pattern 2020 may be connected to the fourth well area W4. For example, the second contact pattern 2020 may be connected to the fourth well area W4 through a fifth contact hole CNT5, a sixth contact hole CNT6, a seventh contact hole CNT7, and an eighth contact hole CNT8. Each of the fifth contact hole CNT5, the sixth contact hole CNT6, the seventh contact hole CNT7, and the eighth contact hole CNT8 may penetrate the second insulating layer.

The third contact pattern 2030 may be connected to the gate electrode of the second transistor T2. For example, the third contact pattern 2030 may be connected to the second gate pattern 1020. For example, the third contact pattern 2030 may be connected to the second gate pattern 1020 through a contact hole. The gate electrode of the second transistor T2 may receive the first scan signal through the third contact pattern 2030.

The fourth contact pattern 2040 may be connected to the second transistor T2. For example, the fourth contact pattern 2040 may be connected to the fourth contact area DA2 of the second transistor T2. For example, the fourth contact pattern 2040 may be connected to the fourth contact area DA2 of the second transistor T2 through a contact hole.

The fifth contact pattern 2050 may be connected to the gate electrode of the third transistor T3. For example, the fifth contact pattern 2050 may be connected to the third gate pattern 1030. For example, the fifth contact pattern 2050 may be connected to the third gate pattern 1030 through a contact hole. The gate electrode of the third transistor T3 may receive the light-emitting control signal through the fifth contact pattern 2050.

The sixth contact pattern 2060 may be connected to the first transistor T1. For example, the sixth contact pattern 2060 may be connected to the second contact area DA1. For example, the sixth contact pattern 2060 may be connected to the second contact area DA1 through a ninth contact hole CNT9 and a tenth contact hole CNT10.

The sixth contact pattern 2060 may be connected to the third transistor T3. For example, the sixth contact pattern 2060 may be connected to the fifth contact area SA3. For example, the sixth contact pattern 2060 may be connected to the fifth contact area SA3 through a contact hole. The first transistor T1 and the third transistor T3 may be connected to each other through the sixth contact pattern 2060. For example, the second contact area DA1 and the fifth contact area SA3 may be connected to each other through the sixth contact pattern 2060.

The seventh contact pattern 2070 may be connected to the third transistor T3. For example, the seventh contact pattern 2070 may be connected to the sixth contact area DA3. For example, the seventh contact pattern 2070 may be connected to the sixth contact area DA3 through a contact hole.

The eighth contact pattern 2080 may be connected to the gate electrode of the fourth transistor T4. For example, the eighth contact pattern 2080 may be connected to the fourth gate pattern 1040. For example, the eighth contact pattern 2080 may be connected to the fourth gate pattern 1040 through a contact hole. The gate electrode of the fourth transistor T4 may receive the second scan signal through the eighth contact pattern 2080.

The ninth contact pattern 2090 may be connected to the fourth transistor T4. For example, the ninth contact pattern 2090 may be connected to the seventh contact area DA4. For example, the ninth contact pattern 2090 may be connected to the seventh contact area DA4 through a contact hole.

The first contact layer SDL1 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other.

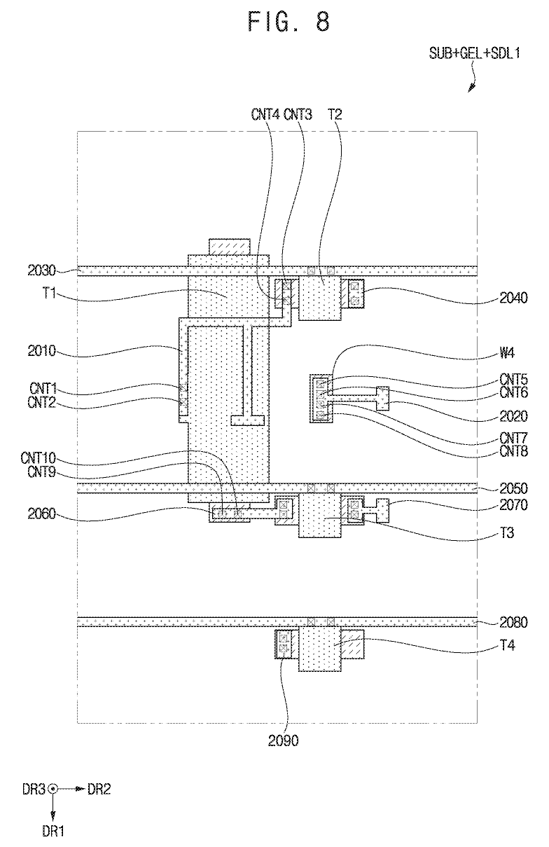

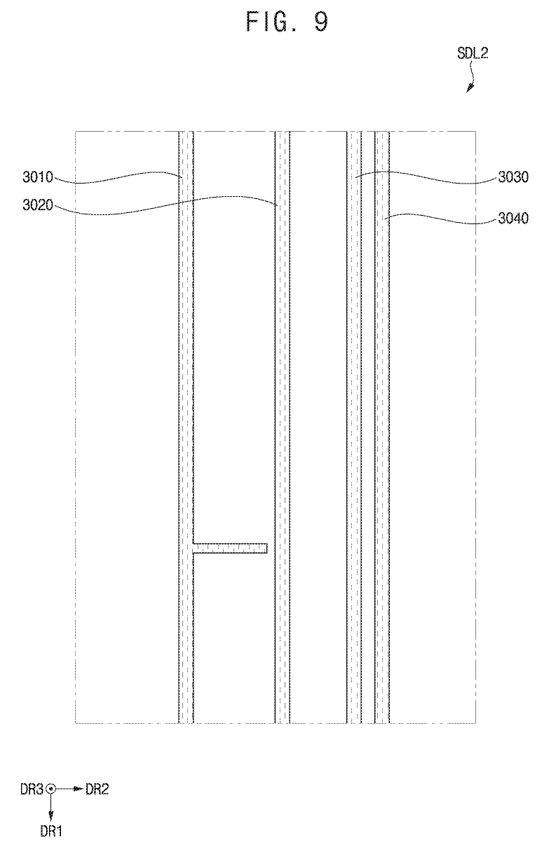

Referring to FIG. 9, the display device may further include a second contact layer SDL2. The second contact layer SDL2 may be located on the first contact layer (e.g., the first contact layer SDL1 of FIG. 8). The second contact layer SDL2 may include a first contact line 3010, a second contact line 3020, a third contact line 3030, and a fourth contact line 3040. The first contact line 3010, the second contact line 3020, the third contact line 3030, and the fourth contact line 3040 may be spaced apart from each other in the plan view.

The reference voltage (e.g., the reference voltage VREF of FIG. 3) may be applied to the first contact line 3010. For example, the first contact line 3010 may substantially correspond to the fourth voltage line (e.g., the fourth voltage line VL4 of FIG. 3), but embodiments of the present disclosure are not necessarily limited thereto. In an embodiment, the first contact line 3010 may include a first portion extending in the first direction DR1 and a second portion extending in the second direction DR2 from the first portion.

The initialization voltage (e.g., the initialization voltage VINT of FIG. 3) may be applied to the second contact line 3020. For example, the second contact line 3020 may substantially correspond to the third voltage line (e.g., the third voltage line VL3 of FIG. 3), but embodiments of the present disclosure are not necessarily limited thereto. The second contact line 3020 may extend in the first direction DR1.

The data voltage (e.g., the data voltage DT of FIG. 3) may be applied to the third contact line 3030. For example, the third contact line 3030 may substantially correspond to the data line (e.g., the data line DL of FIG. 3), but embodiments of the present disclosure are not necessarily limited thereto. The third contact line 3030 may extend in the first direction DR1.

The first power voltage (e.g., the first power voltage ELVDD of FIG. 3) may be applied to the fourth contact line 3040. For example, the fourth contact line 3040 may substantially correspond to the first voltage line (e.g., the first voltage line VL1 of FIG. 3), but embodiments of the present disclosure are not necessarily limited thereto. The fourth contact line 3040 may extend in the first direction DR1.

Referring to FIGS. 4, 8, and 10, the second contact line 3020 may be connected to the fourth transistor T4. For example, the second contact line 3020 may be connected to the seventh contact area SA4. For example, the second contact line 3020 may be connected to the ninth contact pattern 2090 through a contact hole, and as described herein, the ninth contact pattern 2090 may be connected to the seventh contact area SA4 through the contact hole. The fourth transistor T4 may receive the initialization voltage through the second contact line 3020. For example, the seventh contact area SA4 of the fourth transistor T4 may receive the initialization voltage through the second contact line 3020.

The third contact line 3030 may be connected to the second transistor T2. For example, the third contact line 3030 may be connected to the fourth contact area DA2. For example, the third contact line 3030 may be connected to the fourth contact pattern 2040 through a contact hole, and as described herein, the fourth contact pattern 2040 may be connected to the fourth contact area DA2 through the contact hole. The second transistor T2 may receive the data voltage through the third contact line 3030. For example, the fourth contact area DA2 of the second transistor T2 may receive the data voltage through the third contact line 3030.

The fourth contact line 3040 may be connected to the third transistor T3. For example, the fourth contact line 3040 may be connected to the sixth contact area DA3. For example, the fourth contact line 3040 may be connected to the seventh contact pattern 2070 through a contact hole, and as described herein, the seventh contact pattern 2070 may be connected to the sixth contact area DA3 through the contact hole. The third transistor T3 may receive the first power voltage through the fourth contact line 3040. For example, the sixth contact area DA3 of the third transistor T3 may receive the first power voltage through the fourth contact line 3040.

The fourth contact line 3040 may be connected to the second contact pattern 2020. For example, the fourth contact line 3040 may be connected to the second contact pattern 2020 through an eleventh contact hole CNT11 and a twelfth contact hole CNT12. Each of the eleventh contact hole CNT11 and the twelfth contact hole CNT12 may penetrate a portion of the second insulating layer (e.g., the second insulating layer IL2 of FIG. 11). The fourth well area W4 may be connected to the fourth contact line 3040 through the second contact pattern 2020. The fourth well area W4 may receive the first power voltage through the second contact pattern 2020 and the fourth contact line 3040. Accordingly, the features described herein may prevent a portion of the substrate SUB from being affected by unintended electrical signals. For example, the features described herein may prevent the substrate SUB from being affected by the initialization voltage, the data voltage, and/or the like in vicinity of the fourth well area W4.

The second contact layer SDL2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other.

Referring to FIGS. 1, 4, 5, 6, and 8, as described herein, the first gate pattern 1010 may include the first portion 1011 and the second portion 1012. For example, the first gate pattern 1010 may include a concave-convex structure on one surface. The concave-convex structure may correspond to the second portion 1012. The display device DD according to an embodiment may include the concave-convex structure (i.e., the second portion 1012) for connecting the first gate pattern 1010 and the first contact pattern 2010 to each other. The first gate pattern 1010 may include the concave-convex structure in an area in which the first contact hole CNT1 and the second contact hole CNT2 are located. For example, the first gate pattern 1010 may have a rectangular shape with recessed portions which correspond to a first pattern SP1 and a second pattern SP2 which have been removed. The first pattern SP1 and the first portion 1011 may overlap each other in the second direction DR2, and the first pattern SP1 and the second portion 1012 may overlap each other in the first direction DR1. The second pattern SP2 and the first portion 1011 may overlap each other in the second direction DR2, and the second pattern SP2 and the second portion 1012 may overlap each other in the first direction DR1. As the first gate pattern 1010 has a rectangular shape with recessed portions which correspond to the first pattern SP1 and the second pattern SP2 which have been removed, sufficient space for arranging the second transistor T2 and the third transistor T3 may be secured. For example, by removing the unnecessary portions (i.e., the first pattern SP1 and the second pattern SP2) and maintaining the area in which the first contact hole CNT1 and the second contact hole CNT2 are located, sufficient space for arranging the second transistor T2 and the third transistor T3 may be secured. Accordingly, a distance between the first transistor T1 and the second transistor T2 in the plan view may be reduced. In some aspects, a distance between the first transistor T1 and the third transistor T3 in the plan view may be reduced. Accordingly, a pixel driving circuit portion (e.g., the pixel driving circuit portion PXC of FIG. 3) suitable for a high-resolution display device DD may be provided.

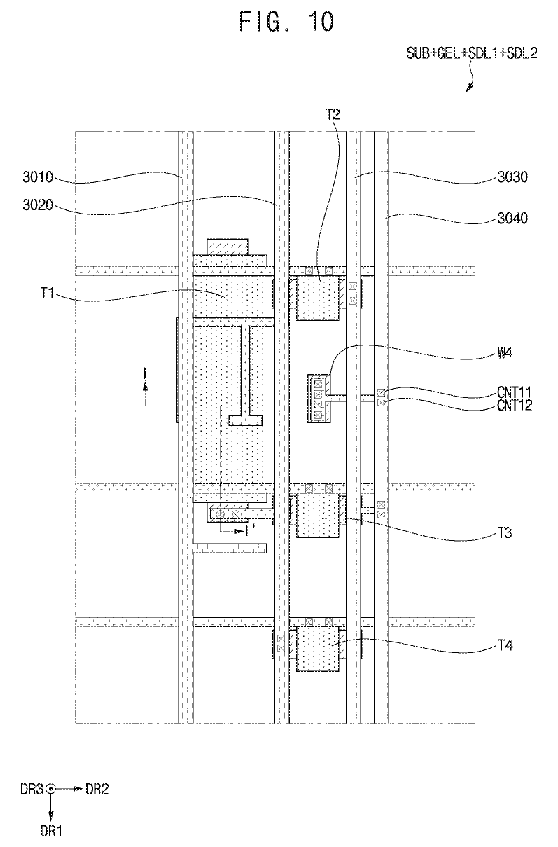

As described herein, the first well area W1 constituting the first transistor T1 may extend in the first direction DR1. For example, a width of the first well area W1 in the first direction DR1 may be greater than a width in the second direction DR2. The fourth well area W4 connected to the fourth contact line (e.g., the fourth contact line 3040 of FIG. 10) may extend in the first direction DR1. For example, a width of the fourth well area W4 in the first direction DR1 may be greater than a width in the second direction DR2. The second well area W2 constituting the second transistor T2 may extend in the second direction DR2. For example, a width of the second well area W2 in the second direction DR2 may be greater than a width in the first direction DR1. The third well area W3 constituting the third transistor T3 may extend in the second direction DR2. For example, a width of the third well area W3 in the second direction DR2 may be greater than a width in the first direction DR1. The fifth well area W5 constituting the fourth transistor T4 may extend in the second direction DR2. For example, a width of the fifth well area W5 in the second direction DR2 may be greater than a width in the first direction DR1. In some aspects, as described herein, the first width XW1 in the first direction DR1 of each of the plurality of pixels PX may be greater than the second width XW2 in the second direction DR2 of each of the plurality of pixels PX. The first well area W1 may extend in a direction parallel to a direction of the first width XW1 (i.e., the first direction DR1). Accordingly, the first transistor T1, the second transistor T2, the third transistor T3, and the fourth transistor T4 may be arranged in two columns. For example, the first transistor T1 may be located in a first column, and each of the second transistor T2, the third transistor T3, and the fourth transistor T4 may be located in a second column. Accordingly, the pixel driving circuit portion (e.g., the pixel driving circuit portion PXC of FIG. 3) suitable for a high-resolution display device DD may be provided.

FIG. 11 is a cross-sectional view taken along the line I-I` of the display device of FIG. 10.

Referring to FIG. 11, the substrate SUB may include the first well area W1. The first well area W1 may include the first channel area CH1 and the second contact area DA1. A first insulating layer IL1 may be located on the substrate SUB. The first insulating layer IL1 may overlap the first gate pattern 1010 in the plan view. The first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other. The first gate pattern 1010 may be located on the first insulating layer IL1.

A second insulating layer IL2 may be located on the first insulating layer IL1. The second insulating layer IL2 may cover the first insulating layer IL1 and the first gate pattern 1010. The second insulating layer IL2 may include the first contact hole CNT1 and the ninth contact hole CNT9. The second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first contact pattern 2010, the fifth contact pattern 2050, and the sixth contact pattern 2060 may be located on the second insulating layer IL2. The first contact pattern 2010 may be connected to the first gate pattern 1010 through the first contact hole CNT1. For example, the first contact pattern 2010 may be connected to the first portion 1011 through the first contact hole CNT1. The sixth contact pattern 2060 may be connected to the second contact area DA1 through the ninth contact hole CNT9.

A third insulating layer IL3 may be located on the second insulating layer IL2. The third insulating layer IL3 may cover the first contact pattern 2010, the fifth contact pattern 2050, and the sixth contact pattern 2060. The third insulating layer IL3 may include inorganic materials such as silicon oxide (“SiOₓ”), silicon nitride (“SiNₓ”), silicon carbide (“SiCₓ”), silicon oxynitride ( “SiOₓN_{y}”), silicon oxycarbide (“SiOₓC_{y}”), and/or the like. These materials may be used alone or in combination with each other. In an embodiment, the third insulating layer IL3 may further include an organic material such as phenolic resin, polyimides resin, polyamides resin, siloxane resin, epoxy resin, and/or the like. These materials may be used alone or in combination with each other.

The first contact line 3010 may be located on the third insulating layer IL3. The fourth insulating layer IL4 may be located on the third insulating layer IL3. The fourth insulating layer IL4 may cover the first contact line 3010. The fourth insulating layer IL4 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other. In an embodiment, the fourth insulating layer IL4 may further include an organic material such as phenolic resin, polyimides resin, polyamides resin, siloxane resin, epoxy resin, and/or the like. These materials may be used alone or in combination with each other.

The display device (e.g., the display device DD of FIG. 1) according to embodiments may be applied to various electronic devices. An electronic device according to embodiments may include the display device described herein, and may further include a module or device having other additional functions in addition to the display device.

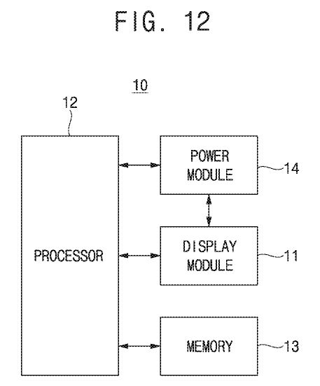

FIG. 12 is a block diagram illustrating an electronic device according to embodiments.

Referring to FIG. 12, an electronic device 10 according to embodiments may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Data information supportive of operations of the processor 12 or the display module 11 may be stored in the memory 15. In an example in which the processor 12 executes an application stored in the memory 15, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power supportive of the operation of the electronic device 10.

At least one of components of the electronic device 10 described herein may be included in the display device according to the embodiments described herein. In some aspects, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

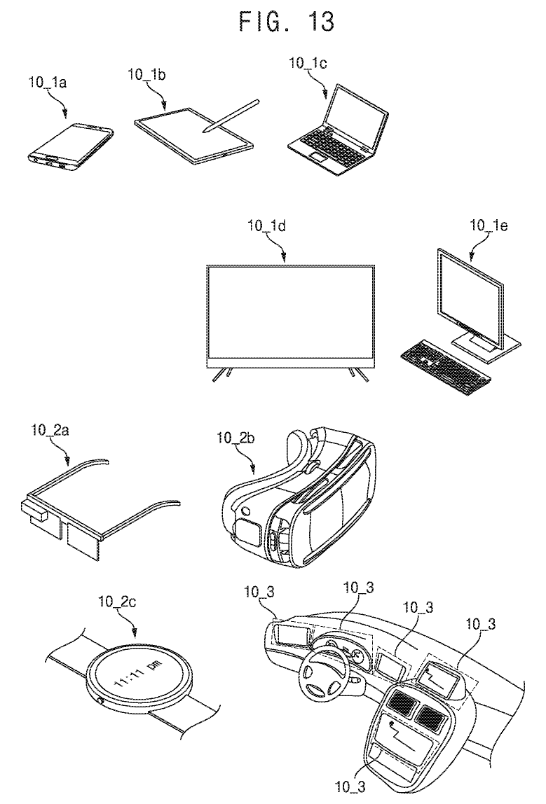

FIG. 13 is a schematic diagram of an electronic device according to various embodiments.

Referring to FIG. 13, various electronic devices to which display devices according to embodiments are applied may include not only electronic devices for image display such as a smartphone 10_1a, a tablet PC 10_1b, a laptop 10_1c, a TV 10_1d, a desk monitor 10_1e, and/or the like, but also wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) disposed on a dashboard, a room mirror display, and/or the like.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although example embodiments have been described, those skilled in the art will readily appreciate that many modifications are possible in the embodiments without materially departing from the novel teachings and advantages of the embodiments of the present disclosure. Accordingly, all such modifications are intended to be included within the scope of the embodiments of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate comprising a first well area comprising:
a first contact area,
a second contact area spaced apart from the first contact area in a plan view, and
a first channel area located between the first contact area and the second contact area;
a first gate pattern located on the substrate and comprising:
a first portion at least partially overlapping the first channel area of the substrate in the plan view, and
a second portion protruding from the first portion; and
a first contact pattern located on the first gate pattern and connected to the second portion of the first gate pattern through a first contact hole.

2. The display device of claim 1, wherein a width of the first portion of the first gate pattern in a first direction is greater than a width of the second portion of the first gate pattern in the first direction.

3. The display device of claim 2, wherein the second portion of the first gate pattern is spaced apart from the first channel area of the substrate in the plan view.

4. The display device of claim 1, wherein a portion of the first well area of the substrate and a portion of the first gate pattern constitute a first transistor that provides a driving current to a light-emitting element.

5. The display device of claim 1, wherein:
the substrate further comprises a second well area comprising a third contact area, a fourth contact area spaced apart from the third contact area in the plan view, and a second channel area located between the third contact area and the fourth contact area, and
the display device further comprises:
a second gate pattern located on the substrate, spaced apart from the first gate pattern in the plan view, and at least partially overlapping the second channel area of the substrate in the plan view.

6. The display device of claim 5, wherein:
the first well area of the substrate extends in a first direction, and
the second well area of the substrate extends in a second direction intersecting the first direction.

7. The display device of claim 6, wherein:
the second contact area of the substrate is spaced apart from the first contact area of the substrate in the first direction, and
the fourth contact area of the substrate is spaced apart from the third contact area of the substrate in the second direction.

8. The display device of claim 6, wherein:
a portion of the first well area of the substrate and a portion of the first gate pattern constitute a first transistor that provides a driving current to a light-emitting element, and
a portion of the second well area of the substrate and a portion of the second gate pattern constitute a second transistor that provides a data voltage to a first node.

9. The display device of claim 5, wherein:
the substrate further comprises:
a third well area comprising a fifth contact area, a sixth contact area spaced apart from the fifth contact area in the plan view, and
a third channel area located between the fifth contact area and the sixth contact area, and
the display device further comprises:
a third gate pattern located on the substrate, spaced apart from the first gate pattern and the second gate pattern in the plan view, and at least partially overlapping the third channel area of the substrate in the plan view.

10. The display device of claim 9, wherein:
the first well area of the substrate extends in a first direction, and
each of the second well area and the third well area of the substrate extends in a second direction intersecting the first direction.

11. The display device of claim 5, wherein the first contact pattern is connected to the third contact area of the substrate through a third contact hole.

12. The display device of claim 1, wherein:
the substrate further comprises a fourth well area spaced apart from the first well area in the plan view, and
the display device further comprises:
a second contact pattern located on the first gate pattern and connected to the fourth well area through a fifth contact hole; and
a fourth contact line located on the second contact pattern, to which a first power voltage is applied, and connected to the second contact pattern through an eleventh contact hole.

13. The display device of claim 12, wherein each of the first well area and the fourth well area of the substrate extends in a first direction.

14. The display device of claim 1, wherein:
the first gate pattern is located in a display area in which pixel is arranged,
a width of the pixel in a first direction is greater than a width of the pixel in a second direction intersecting the first direction, and
the first well area extends in the first direction.

15. A display device comprising:
a substrate comprising:
a first well area comprising a first contact area, a second contact area spaced apart from the first contact area in a plan view, and a first channel area located between the first contact area and the second contact area and extending in a first direction; and
a second well area comprising a third contact area, a fourth contact area spaced apart from the third contact area in the plan view, and a second channel area located between the third contact area and the fourth contact area and extending in a second direction intersecting the first direction;
a first gate pattern located on the substrate and at least partially overlapping the first channel area of the substrate in the plan view; and
a second gate pattern located on the substrate, spaced apart from the first gate pattern in the plan view, and at least partially overlapping the second channel area of the substrate in the plan view.

16. The display device of claim 15, wherein:
a portion of the first well area of the substrate and a portion of the first gate pattern constitute a first transistor that provides a driving current to a light-emitting element, and
a portion of the second well area of the substrate and a portion of the second gate pattern constitute a second transistor that provides a data voltage to a first node.

17. The display device of claim 15, wherein:
the substrate further comprises a third well area extending in the second direction and comprising a fifth contact area, a sixth contact area spaced apart from the fifth contact area in the plan view, and a third channel area located between the fifth contact area and the sixth contact area, and
the display device further comprises:
a third gate pattern located on the substrate, spaced apart from the first gate pattern and the second gate pattern in the plan view, and at least partially overlapping the third channel area of the substrate in the plan view.

18. An electronic device comprising:
a substrate comprising a first well area comprising:\a first contact area,
a second contact area spaced apart from the first contact area in a plan view, and
a first channel area located between the first contact area and the second contact area;
a first gate pattern located on the substrate and comprising:
a first portion at least partially overlapping the first channel area of the substrate in the plan view, and
a second portion protruding from the first portion;
a first contact pattern located on the first gate pattern and connected to the second portion of the first gate pattern through a first contact hole; and
a memory configured to store data information.

19. The electronic device of claim 18, wherein a width of the first portion of the first gate pattern in a first direction is greater than a width of the second portion of the first gate pattern in the first direction.

20. The electronic device of claim 19, wherein the second portion of the first gate pattern is spaced apart from the first channel area of the substrate in the plan view.
